(19) United States
(12) Patent Application Publication
(10) Pub. No.: US 2025/0007445 A1
(43) Pub. Date: Jan. 2, 2025

(54) INTEGRATED PHOTOVOLTAIC ROOFING SHINGLES, METHODS, SYSTEMS, AND KITS THEREOF

(71) Applicant: GAF Energy LLC, Parsippany, NJ (US)

(72) Inventors: Nathan Peterson, Oakland, CA (US); Richard Perkins, San Jose, CA (US); Alex Sharenko, Berkeley, CA (US); Gabriela Bunea, San Jose, CA (US)

(21) Appl. No.: 18/758,675

(22) Filed: Jun. 28, 2024

Related U.S. Application Data
(63) Continuation of application No. 17/966,618, filed on Oct. 14, 2022, now Pat. No. 12,051,990.
Application No. 17/966,618 is a continuation of application No. 17/154,809, filed on Jan. 21, 2021, now Pat. No. 11,489,482.
(60) Provisional application No. 62/964,451, filed on Jan. 22, 2020.

(51) Int. Cl. H02S 20/25; B32B 37/26; H01L 31/048

(52) U.S. Cl. CPC H02S 20/25; B32B 37/26; H01L 31/0481; B32B 2274/00; B32B 2457/12

(57) ABSTRACT

Some embodiments of the present disclosure relate to an integrated photovoltaic (PV) roofing shingle comprising a photovoltaic (PV) module and a roofing shingle. In some embodiments, the roofing shingle is bonded to the PV module. In some embodiments, a bond strength between the roofing shingle and the PV module is from 5 N/mm to 60 N/mm tested according to ASTM D1876. In some embodiments, the integrated PV roofing shingle has a mass per unit area of 0.5 lb per square foot to 5 lbs per square foot. Methods, systems, and kits including the integrated PV roofing shingle are also disclosed.

### CROSS-REFERENCE TO RELATED APPLICATION

This application is a continuation of U.S. patent application Ser. No. 17/966,618, filed on Oct. 14, 2022, entitled “INTEGRATED PHOTOVOLTAIC ROOFING SHINGLES, METHODS, SYSTEMS, AND KITS THEREOF,” continuation of U.S. patent application Ser. No. 17/154,809, filed on Jan. 21, 2021, now U.S. Pat. No. 11,489,482, entitled “INTEGRATED PHOTOVOLTAIC ROOFING SHINGLES, METHODS, SYSTEMS, AND KITS THEREOF,” which claims the benefit of U.S. Provisional Application Ser. No. 62/964,451, filed on Jan. 22, 2020, entitled “INTEGRATED PHOTOVOLTAIC ROOFING SHINGLES, METHODS, SYSTEMS, AND KITS THEREOF,” the contents of which are incorporated herein by reference in their entirety.

### FIELD

The present disclosure relates to integration of photovoltaic (PV) panels into roofing shingles.

### BACKGROUND

Traditional rooftop photovoltaic (PV) systems require a large amount of installation labor, as well as specialized tools and methods. Mechanisms to reduce the amount of labor and limit specific requirements for installing PV by making the installation more similar to that of a rooftop shingle are needed.

### SUMMARY

Covered embodiments are defined by the claims, not this summary. This summary is a high-level overview of various aspects and introduces some of the concepts that are further described in the Detailed Description section below. This summary is not intended to identify key or essential features of the claimed subject matter, nor is it intended to be used in isolation to determine the scope of the claimed subject matter. The subject matter should be understood by reference to appropriate portions of the entire specification, any or all drawings, and each claim.

Some embodiments of the present disclosure relate to an integrated photovoltaic (PV) roofing shingle comprising: a photovoltaic (PV) module; and a roofing shingle, wherein the roofing shingle is bonded to the PV module; wherein a bond strength between the roofing shingle and the PV module is from 5 N/mm to 60 N/mm tested according to ASTM D1876 wherein the integrated PV roofing shingle has a mass per unit area of 0.5 lb per square foot to 5 lbs per square foot.

In some embodiments, the roofing shingle is bonded to the PV module by at least one adhesive.

In some embodiments, the roofing shingle is a polymer-coated shingle, an asphalt-coated shingle, or a combination thereof.

In some embodiments, the polymer-coated shingle comprises thermoplastic polyolefin.

In some embodiments, the PV module comprises at least one of: a substrate, wherein the substrate forms at least a portion of a bottom surface of the PV module; a superstrate, wherein the superstrate forms at least a portion of a top surface of the PV module; or any combination thereof.

In some embodiments, the roofing shingle is bonded to at least one of: the substrate, the superstrate, or any combination thereof.

In some embodiments, the top surface of the PV module comprises: a first portion, wherein the first portion of the top surface of the PV module comprises the superstrate; and a second portion, wherein the second portion of the top surface of the PV module does not comprise the superstrate; wherein the roofing shingle is bonded to the second portion of the top surface of the PV module; and wherein the second portion of the top surface of the PV module is adjacent to the first portion of the top surface of the PV module.

In some embodiments, the bottom surface of the PV module does not comprise a substrate, and wherein the roofing shingle is bonded to the bottom surface.

Some embodiments of the present disclosure relate to a method comprising: obtaining a photovoltaic (PV) module and a roofing shingle; bonding the PV module to the roofing shingle, so as to form an integrated PV roofing shingle having a bond strength, between the roofing shingle and the PV module of from 5 N/mm to 60 N/mm tested according to ASTM D1876; and wherein the integrated PV roofing shingle has a mass per unit area of 0.5 lb per square foot to 5 lbs per square foot.

In some embodiments, the bonding step comprises laminating the PV module to the roofing shingle.

In some embodiments, the bonding step comprises bonding the PV module to the roofing shingle with a sufficient amount of bonding material.

Some embodiments of the present disclosure relate to a method comprising: obtaining an integrated PV roofing shingle comprising: a photovoltaic (PV) module; and a roofing shingle, wherein the roofing shingle is bonded to the PV module; wherein a bond strength between the roofing shingle and the PV module is from 5 N/mm to 60 N/mm tested according to ASTM D1876; wherein the integrated PV roofing shingle has a mass per unit area of 0.5 lb per square foot to 5 lbs per square foot; and affixing the integrated PV roofing shingle to a roof.

In some embodiments, the affixing step comprises affixing the integrated PV roofing shingle to the roof using at least one fastener.

In some embodiments, the at least one fastener is chosen from at least one nail, at least one screw, at least one staple, or any combination thereof.

In some embodiments, the integrated PV roofing shingle has 1 fastener to 5 fasteners per square foot of the integrated PV roofing shingle after the affixing step.

In some embodiments, the fastener is affixed to the roof by driving the fastener through an overlapping area of the integrated PV roofing shingle and into the roof.

Some embodiments of the present disclosure relate to a roofing kit comprising: a plurality of integrated PV roofing shingles, wherein each integrated PV roofing shingle of the plurality of integrated PV roofing shingles comprises: a photovoltaic (PV) module; and a roofing shingle, wherein each roofing shingle of the plurality is bonded to a corresponding PV module; wherein a bond strength between each roofing shingle and each corresponding PV module of the plurality is from 5 N/mm to 60 N/mm tested according to ASTM D1876; wherein each integrated PV roofing shingle of the plurality has a mass per unit area of 0.5 lb per square foot to 5 lbs per square foot; and wherein each integrated PV roofing shingle of the plurality is configured to be affixed to a roof by at least one fastener.

### BRIEF DESCRIPTION OF THE DRAWINGS

Some embodiments of the disclosure are herein described, by way of example only, with reference to the accompanying drawings. With specific reference now to the drawings in detail, it is stressed that the embodiments shown are by way of example and for purposes of illustrative discussion of embodiments of the disclosure. In this regard, the description taken with the drawings makes apparent to those skilled in the art how embodiments of the disclosure may be practiced.

FIGS. 1-4 are non-limiting embodiments, in cross sectional views, of exemplary integrated PV roofing shingles according to the present disclosure.

FIG. 5 is a top view of an illustrative non-limiting exemplary embodiment of an integrated PV roofing shingle according to the present disclosure.

### DETAILED DESCRIPTION

Among those benefits and improvements that have been disclosed, other objects and advantages of this disclosure will become apparent from the following description taken in conjunction with the accompanying figures. Detailed embodiments of the present disclosure are disclosed herein; however, it is to be understood that the disclosed embodiments are merely illustrative of the disclosure that may be embodied in various forms. In addition, each of the examples given regarding the various embodiments of the disclosure which are intended to be illustrative, and not restrictive.

Throughout the specification and claims, the following terms take the meanings explicitly associated herein, unless the context clearly dictates otherwise. The phrases “in one embodiment,” “in an embodiment,” and “in some embodiments” as used herein do not necessarily refer to the same embodiment(s), though it may. Furthermore, the phrases “in another embodiment” and “in some other embodiments” as used herein do not necessarily refer to a different embodiment, although it may. All embodiments of the disclosure are intended to be combinable without departing from the scope or spirit of the disclosure.

As used herein, the term “based on” is not exclusive and allows for being based on additional factors not described, unless the context clearly dictates otherwise. In addition, throughout the specification, the meaning of “a,” “an,” and “the” include plural references. The meaning of “in” includes “in” and “on.”

As used herein, terms such as “comprising” “including,” and “having” do not limit the scope of a specific claim to the materials or steps recited by the claim.

As used herein, the term “consisting essentially of” limits the scope of a specific claim to the specified materials or steps and those that do not materially affect the basic and novel characteristic or characteristics of the specific claim.

As used herein, terms such as “consisting of” and “composed of” limit the scope of a specific claim to the materials and steps recited by the claim.

All prior patents, publications, and test methods referenced herein are incorporated by reference in their entireties.

As used herein, the term photovoltaic (“PV”) module refers to any device that is configured to convert light (e.g., sunlight) into electric power. A non-limiting example of a PV module is a solar panel.

As used herein, the term “integrated PV roofing shingle” or “integrated photovoltaic roofing shingle” refers to a roofing shingle that includes a PV module and a roofing shingle, where the PV module and roofing shingle collectively function a single, stand-alone unit. In some embodiments, the “integrated PV roofing shingle” functions as a single, stand-alone unit regardless of whether the “integrated PV roofing shingle” is installed on a roof. While a single integrated PV roofing shingle may function as a stand-alone unit, this does not preclude, for example, some embodiments where multiple integrated PV roofing shingles function together as a system.

As used herein, the term “bonded” means that two surfaces (e.g., a surface of a PV module and a surface of a roofing shingle) are in sufficient contact with each other to provide any bond strength or range of bond strengths described herein.

As used herein, the term “superstrate” refers to a layer of a material disposed on a top (i.e., sun-facing) portion of a PV module.

As used herein, the term “substrate” refers to a layer of a material disposed on a bottom (i.e., ground-facing) portion of a PV module.

In some embodiments, the layer of material of the substrate, the superstrate, or any combination thereof comprises an insulating moisture resistant polymer, such as, but not limited to thermoplastic polyolefin (TPO), Ethylene tetrafluoroethylene (ETFE), polyolefin encapsulant (POE), ethylene vinyl acetate encapsulant (EVA), and acrylics. In some embodiments, the layer of material of the substrate, the superstrate, or any combination thereof comprises glass.

As used herein, the term “overlapping area” is defined as the multi-layered section of a shingle where a portion of the headlap section of the shingle overlaps and contacts a portion of the lower layer of the shingle. In embodiments, the overlapping portion of the headlap section of the shingle is bonded to the corresponding portion of the lower layer of the shingle. In embodiments, the overlapping portion of the headlap section of the shingle is bonded to the corresponding portion of the lower layer of the shingle using an adhesive, fastener or combination thereof. In some embodiments, the overlapping portion of the headlap section of the shingle is bonded to the corresponding portion of the lower layer of the shingle as detailed in U.S. Pat. No. 8,127,514, which is incorporated by reference in its entirety.

Some embodiments of the present disclosure relate to an integrated PV roofing shingle. In some embodiments, the integrated PV roofing shingle comprises a PV module and a roofing shingle.

In some embodiments, the roofing shingle is bonded to the PV module. In some embodiments, the roofing shingle is bonded to the PV module by laminating the PV module to the roofing shingle. In some embodiments, the roofing shingle is bonded to the PV module by at least one bonding material. In some embodiments, the at least one bonding material comprises at least one adhesive. In embodiments, the at least one adhesive includes at least one of: asphaltic adhesives such as rubber polymer modified asphalt, acrylic adhesives, polyurethane adhesives, silicone adhesives, rubber polymer based adhesives, e.g. SBS, SBR, SEBS and SIS, or any combination thereof.

In some embodiments, a bond strength between the roofing shingle and the PV module is from 5 N/mm to 60 N/mm tested according to ASTM D1876, from 10 N/mm to 60 N/mm according to ASTM D1876, from 15 N/mm to 60 N/mm according to ASTM D1876, from 20 N/mm to 60 N/mm according to ASTM D1876, from 25 N/mm to 60 N/mm according to ASTM D1876, from 30 N/mm to 60 N/mm according to ASTM D1876, from 35 N/mm to 60 N/mm according to ASTM D1876, from 40 N/mm to 60 N/mm according to ASTM D1876, from 45 N/mm to 60 N/mm according to ASTM D1876, from 50 N/mm to 60 N/mm according to ASTM D1876, or from 55 N/mm to 60 N/mm according to ASTM D1876.

In some embodiments, a bond strength between the roofing shingle and the PV module is from 5 N/mm to 55 N/mm tested according to ASTM D1876, from 5 N/mm to 50 N/mm according to ASTM D1876, from 5 N/mm to 45 N/mm according to ASTM D1876, from 5 N/mm to 40 N/mm according to ASTM D1876, from 5 N/mm to 35 N/mm according to ASTM D1876, from 5 N/mm to 30 N/mm according to ASTM D1876, from 5 N/mm to 25 N/mm according to ASTM D1876, from 5 N/mm to 20 N/mm according to ASTM D1876, from 5 N/mm to 15 N/mm according to ASTM D1876, or from 5 N/mm to 10 N/mm according to ASTM D1876.

In some embodiments, a bond strength between the roofing shingle and the PV module is from 10 N/mm to 55 N/mm tested according to ASTM D1876, from 15 N/mm to 50 N/mm according to ASTM D1876, from 20 N/mm to 45 N/mm according to ASTM D1876, from 25 N/mm to 40 N/mm according to ASTM D1876, or from 30 N/mm to 35 N/mm according to ASTM D1876.

In some embodiments, the roofing shingle is an asphalt-coated shingle, a polymer-coated shingle or any combination/mixture thereof. Non-limiting examples of the polymer coatings include, thermoplastic polyolefin (TPO), polyvinyl butyral (rPVB), polytransoctenamer rubber (TOR), ground tire rubber (GTR), wood plastic, poly(methyl methacrylate) (PMMA), polyvinyl chloride (PVC), low density polyethylene (LDPE), high density polyethylene (HDPE), polypropylene (PP), polyethylene terephthalate (PET). Non-limiting examples of asphalt coatings include oxidized asphalt coatings and polymer modified asphalt coatings. Non-limiting examples of polymer modified asphalt coated shingles are described in U.S. Pat. No. 9,493,654, which is incorporated by reference herein in its entirety.

In some embodiments, the integrated PV roofing shingle has a mass per unit area from 0.5 lb per square foot to 5 lbs per square foot, from 0.5 lb per square foot to 4.5 lbs per square foot, 0.5 lb per square foot to 4 lbs per square foot, from 0.5 lb per square foot to 3.5 lbs per square foot, from 0.5 lb per square foot to 3 lbs per square foot, from 0.5 lb per square foot to 2.5 lbs per square foot, from 0.5 lb per square foot to 2 lbs per square foot, from 0.5 lb per square foot to 1.5 lbs per square foot, or from 0.5 lb per square foot to 1 lbs per square foot.

In some embodiments, the integrated PV roofing shingle has a mass per unit area from 1 lb per square foot to 5 lbs per square foot, from 1.5 lb per square foot to 5 lbs per square foot, from 2 lb per square foot to 5 lbs per square foot, from 2.5 lb per square foot to 5 lbs per square foot, from 3 lb per square foot to 5 lbs per square foot, from 3.5 lb per square foot to 5 lbs per square foot, from 4 lb per square foot to 5 lbs per square foot, or from 4.5 lb per square foot to 5 lbs per square foot.

In some embodiments, the integrated PV roofing shingle has a mass per unit area of 1 lbs per square foot to 4.5 lbs per square foot, from 1.5 lb per square foot to 4 lbs per square foot, from 2 lb per square foot to 3.5 lbs per square foot, or from 2.5 lb per square foot to 3 lbs per square foot.

In some embodiments, the PV module comprises at least one of: a substrate, a superstrate, or any combination thereof. In some embodiments, the roofing shingle is bonded to at least one of: the substrate, the superstrate, or any combination thereof.

In some embodiments, the substrate forms at least a portion of a bottom surface of the PV module. In some embodiments, the substrate forms the entire bottom surface of the PV module. In some embodiments, the superstrate forms at least a portion of a top surface of the PV module. In some embodiments, the superstrate forms the entire top surface of the PV module.

In some embodiments, the bottom surface of the PV module does not comprise a substrate. In some embodiments, the roofing shingle is bonded to the bottom surface of the PV module, such that the roofing shingle replaces the substrate of the PV module. A non-limiting example of an embodiment where a roofing shingle replaces the substrate of a PV module is shown in FIG. 3 and described in more detail below.

In some embodiments, the top surface of the PV module does not comprise a substrate. In some embodiments, the roofing shingle is bonded to the top surface of the PV module, such that the roofing shingle replaces the superstrate of the PV module.

In some embodiments, the top surface of the PV module comprises a first portion and a second portion. In some embodiments, the second portion of the top surface of the PV module is adjacent to the first portion of the top surface. In some embodiments, the first portion of the top surface of the PV module comprises the superstrate. In some embodiments, the second portion of the top surface of the PV module does not comprise the superstrate. In some embodiments, the roofing shingle is bonded to the second portion of the top surface of the PV module, such that the roofing shingle replaces the superstrate on the second portion of the top surface of the PV module. A non-limiting example of an embodiment where a roofing shingle replaces the superstrate on the second portion of the top surface of the PV module is shown in FIG. 4 and described in more detail below.

In some embodiments, the bottom surface of the PV module comprises a first portion and a second portion. In some embodiments, the second portion of the bottom surface of the PV module is adjacent to the first portion of the bottom surface. In some embodiments, the first portion of the bottom surface of the PV module comprises the substrate. In some embodiments, the second portion of the bottom surface of the PV module does not comprise the substrate. In some embodiments, the roofing shingle is bonded to the second portion of the bottom surface of the PV module, such that the roofing shingle replaces the substrate on the second portion of the bottom surface of the PV module.

Some embodiments of the present disclosure relate to a method of manufacturing an integrated PV roofing shingle described herein. In some embodiments, the method comprises obtaining a PV module and a roofing shingle. In some embodiments, the method comprises bonding the PV module to the roofing shingle, so as to form an integrated PV roofing shingle having a bond strength, between the roofing shingle and the PV module, described herein.

In some embodiments, bonding the PV module to the roofing shingle comprises bonding the PV module to the roofing shingle with a sufficient amount of bonding material, including for example, an adhesive, described herein. In some embodiments, the bonding the PV module to the roofing shingle comprises laminating the PV module to the roofing shingle.

Some embodiments of the present disclosure relate to a method of installing an integrated PV roofing shingle described herein onto a roof. In some embodiments, the method comprises obtaining an integrated PV roofing shingle described herein and affixing the integrated PV roofing shingle to a roof. In some embodiments, the integrated PV roofing shingle described herein is affixed to a specific portion of a roof. In some embodiments, the specific portion of the roof where the integrating roofing shingle is affixed is a roof deck.

In some embodiments, affixing comprises affixing the integrated PV roofing shingle to the roof using at least one fastener. In some embodiments, the at least one fastener is chosen from at least one nail, at least one screw, at least one staple, or any combination thereof. In some embodiments, the fastener is affixed to the roof by driving the fastener through an overlapping area (as defined herein) of the integrated PV roofing shingle and into the roof.

In some embodiments, affixing comprises affixing the integrated PV roofing shingle to the roof using an adhesive. In embodiments, the adhesive may include at least one of: asphaltic adhesives such as rubber polymer modified asphalt, acrylic adhesives, polyurethane adhesives, silicone adhesives, rubber polymer based adhesives, e.g. SBS, SBR, SEBS and SIS, or any combination thereof.

In some embodiments, the integrated PV roofing shingle has from 1 fastener to 5 fasteners per square foot of the integrated PV roofing shingle when the integrated PV roofing shingle is installed on a roof. In some embodiments, the integrated PV roofing shingle has from 2 fasteners to 5 fasteners per square foot of the integrated PV roofing shingle when the integrated PV roofing shingle is installed on a roof. In some embodiments, the integrated PV roofing shingle has from 3 fasteners to 5 fasteners per square foot of the integrated PV roofing shingle when the integrated PV roofing shingle is installed on a roof. In some embodiments, the integrated PV roofing shingle has from 4 fasteners to 5 fasteners per square foot of the integrated PV roofing shingle when the integrated PV roofing shingle is installed on a roof.

In some embodiments, the integrated PV roofing shingle has from 1 fastener to 4 fasteners per square foot of the integrated PV roofing shingle when the integrated PV roofing shingle is installed on a roof. In some embodiments, the integrated PV roofing shingle has from 1 fastener to 3 fasteners per square foot of the integrated PV roofing shingle when the integrated PV roofing shingle is installed on a roof. In some embodiments, the integrated PV roofing shingle has from 1 fastener to 2 fasteners per square foot of the integrated PV roofing shingle when the integrated PV roofing shingle is installed on a roof.

In some embodiments, the integrated PV roofing shingle has from 2 fasteners to 3 fasteners per square foot of the integrated PV roofing shingle when the integrated PV roofing shingle is installed on a roof. In some embodiments, the integrated PV roofing shingle has from 2 fasteners to 4 fasteners per square foot of the integrated PV roofing shingle when the integrated PV roofing shingle is installed on a roof. In some embodiments, the integrated PV roofing shingle has from 3 fasteners to 4 fasteners per square foot of the integrated PV roofing shingle when the integrated PV roofing shingle is installed on a roof.

Some embodiments of the present disclosure relate to a roofing kit. In some embodiments, the roofing kit comprises a plurality of integrated PV roofing shingles described herein. In some embodiments, the roofing kit comprises two integrated PV roofing shingles described herein. In some embodiments, the roofing kit comprises three integrated PV roofing shingles described herein. In some embodiments, the roofing kit comprises four integrated PV roofing shingles described herein. In some embodiments, the roofing kit comprises five integrated PV roofing shingles described herein. In some embodiments, the roofing kit comprises six integrated PV roofing shingles described herein. In some embodiments, the roofing kit comprises seven integrated PV roofing shingles described herein. In some embodiments, the roofing kit comprises eight integrated PV roofing shingles described herein. In some embodiments, the roofing kit comprises nine integrated PV roofing shingles described herein. In some embodiments, the roofing kit comprises ten integrated PV roofing shingles described herein. In some embodiments, the roofing kit comprises twenty integrated PV roofing shingles described herein. In some embodiments, the roofing kit comprises thirty integrated PV roofing shingles described herein. In some embodiments, the roofing kit comprises forty integrated PV roofing shingles described herein. In some embodiments, the roofing kit comprises fifty integrated PV roofing shingles described herein. In some embodiments, the roofing kit comprises one-hundred integrated PV roofing shingles described herein. In some embodiments, the roofing kit comprises five-hundred integrated PV roofing shingles described herein.

In some embodiments, each integrated PV roofing shingle of the roofing kit is configured to be affixed to a roof by at least one fastener described herein.

The present disclosure will now be described with reference to several non-limiting exemplary embodiments.

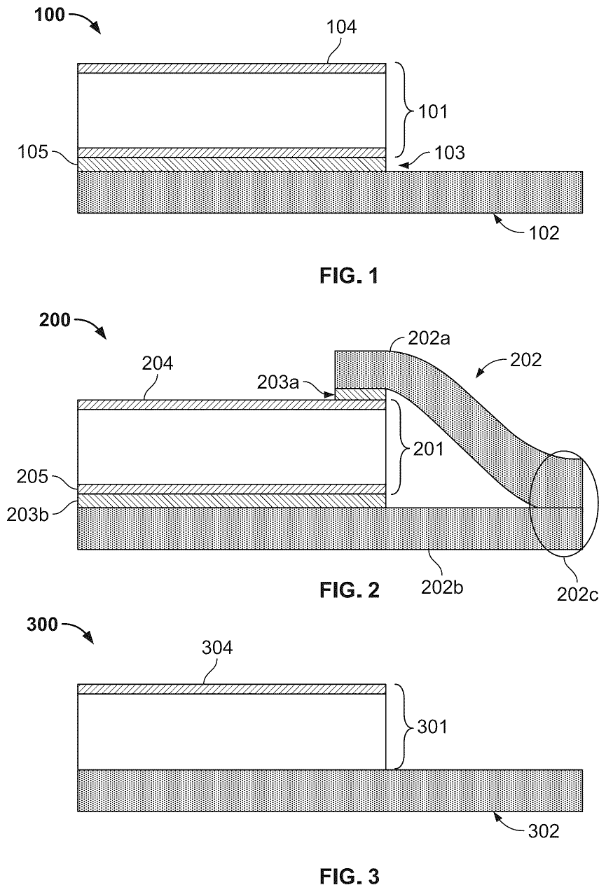

FIG. 1 depicts an illustrative non-limiting exemplary embodiment of an integrated PV roofing shingle according to the present disclosure shown in cross-section. As shown in FIG. 1, an integrated PV roofing shingle 100 may comprise a PV module 101 bonded to a roofing shingle 102. In some embodiments, the integrated PV roofing shingle 100 may comprise a bonding material 103 between the roofing shingle 102 and the PV module 101. In some embodiments, the PV module 101 of the integrated PV roofing shingle 100 may comprise a superstrate 104 and a substrate 105.

FIG. 2 depicts an illustrative non-limiting exemplary embodiment of an integrated PV roofing shingle according to the present disclosure, also shown in cross-section. As shown in FIG. 2, integrated PV roofing shingle 200 may comprise a PV module 201 bonded to a roofing shingle 202. Roofing shingle 202 may, in some embodiments, comprise two portions—first portion 202a and second portion 202b. In some embodiments, first portion 202a is a top portion as shown. In some embodiments, second portion 202b is a bottom portion as shown. However, this configuration is not limiting. The first portion 202a and second portion 202b of the roofing shingle 202 may, in some embodiments, be in contact at overlapping area 202c. In some embodiments, at least one fastener (not shown) may be driven into overlapping area 202c, so as to affix integrated PV roofing shingle 200 to a roof (not shown). In some embodiments, the integrated PV roofing shingle 200 may comprise a first bonding material 203a and a second bonding material 203b. In some embodiments, first bonding material 203a and second bonding material 203b are the same. In some embodiments, first bonding material 203a and second bonding material 203b are different. In some embodiments, the PV module 201 of the integrated PV roofing shingle 200 may comprise a superstrate 204 and a substrate 205. In some embodiments, first bonding material 203a is disposed between the superstrate 204 and the first portion 202a of the roofing shingle 202. In some embodiments, second bonding material 203b is disposed between the substrate 205 and the first portion 202b of the roofing shingle 202.

FIG. 3 depicts an illustrative non-limiting exemplary embodiment of an integrated PV roofing shingle according to the present disclosure, also in cross-section. As shown in FIG. 3, integrated PV roofing shingle 300 may comprise a PV module 301 bonded to a roofing shingle 302. In some embodiments, the PV module 301 of the integrated PV roofing shingle 300 may comprise a superstrate 304. In some embodiments, the PV module 301 of the integrated PV roofing shingle 300 may not include a substrate, such that the roofing shingle 302 replaces the substrate, as shown.

FIG. 4 depicts an illustrative non-limiting exemplary embodiment of an integrated PV roofing shingle according to the present disclosure in cross-section. Roofing shingle 402 may, in some embodiments, comprise two portions—first portion 402a and second portion 402b. The first portion 402a and second portion 402b of the roofing shingle 402 may, in some embodiments, be in contact at overlapping area 402c. In some embodiments, a fastener (not shown) may be driven into overlapping area 402c, so as to affix integrated PV roofing shingle 400 to a roof (not shown). In some embodiments, the PV module 401 of the integrated PV roofing shingle 400 may comprise a superstrate 404. In some embodiments, a top portion 401a of the PV module 401 does not comprise the superstrate 404. In some such embodiments, a portion of the superstrate 404 is replaced with portion 402d of the roofing shingle 402 on top portion 401a of the PV module as shown. In some embodiments, the portion 402d of the roofing shingle 402 that is disposed on top portion 401a of the PV module 401 is adjacent to the superstrate 404 as shown.

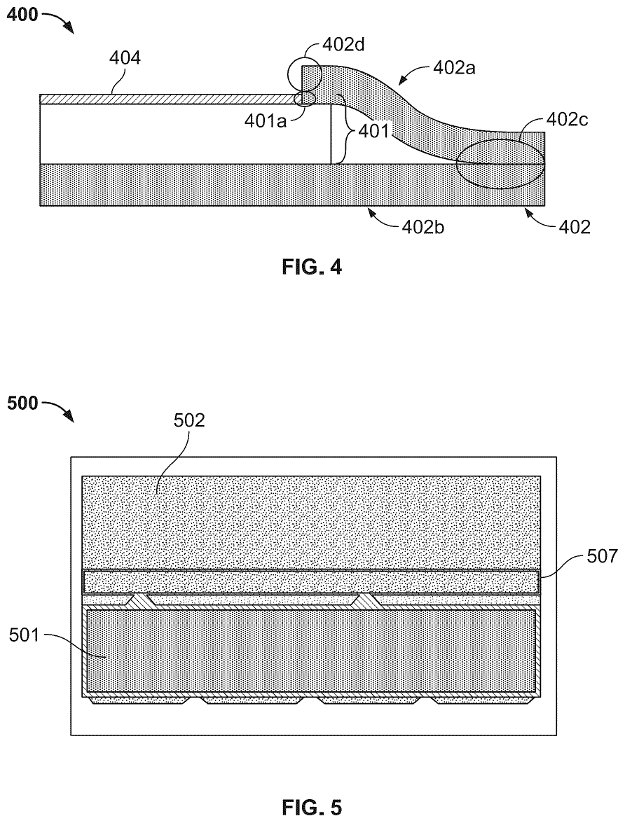

FIG. 5 depicts a top view of an illustrative non-limiting exemplary embodiment of an integrated PV roofing shingle according to the present disclosure. As shown in FIG. 5, integrated PV roofing shingle 500 may comprise a PV module 501 bonded to a roofing shingle 502. In some embodiments, integrated PV roofing shingle 500 may comprise a fastener application area 507.

Variations, modifications and alterations to embodiments of the present disclosure described above will make themselves apparent to those skilled in the art. All such variations, modifications, alterations and the like are intended to fall within the spirit and scope of the present disclosure, limited solely by the appended claims.

While several embodiments of the present disclosure have been described, it is understood that these embodiments are illustrative only, and not restrictive, and that many modifications may become apparent to those of ordinary skill in the art. For example, all dimensions discussed herein are provided as examples only, and are intended to be illustrative and not restrictive.

Any feature or element that is positively identified in this description may also be specifically excluded as a feature or element of an embodiment of the present as defined in the claims.

The disclosure described herein may be practiced in the absence of any element or elements, limitation or limitations, which is not specifically disclosed herein. Thus, for example, in each instance herein, any of the terms “comprising,” “consisting essentially of and “consisting of” may be replaced with either of the other two terms, without altering their respective meanings as defined herein. The terms and expressions which have been employed are used as terms of description and not of limitation, and there is no intention in the use of such terms and expressions of excluding any equivalents of the features shown and described or portions thereof, but it is recognized that various modifications are possible within the scope of the disclosure.

1-18. (canceled)

19. A system, comprising:
a plurality of photovoltaic (PV) roofing shingles installed on a roof deck,
wherein the plurality of PV roofing shingles includes at least a first PV roofing shingle and a second PV roofing shingle,
wherein each of the plurality of PV roofing shingles includes
a PV module, wherein the PV module includes
a superstrate,
a substrate, and
a first layer between the superstrate and the substrate, and
a roofing layer,
wherein the roofing layer includes
a substantially flat top surface, and
a substantially flat bottom surface opposite the substantially flat top surface,
wherein the substantially flat bottom surface of the first PV roofing shingle overlaps the substantially flat top surface of the second PV roofing shingle, and
wherein the roofing layer of the first PV roofing shingle partially overlaps and contacts the roofing layer of the second PV roofing shingle.

20. The system of claim 19, wherein the substantially flat top surface defines a fastener application area, wherein the roofing layer includes a first end, a second end opposite to the first end, a first edge extending between the first end and the second end, a second edge opposite to the first edge and extending between the first end and the second end, and wherein the fastener application area is between the first edge and from the second edge and extends from the first end of the roofing layer to the second end of the roofing layer.

21. The system of claim 20, further comprising at least one fastener, wherein the at least one fastener penetrates the fastener application area of at least one of the first PV roofing shingle and the second PV roofing shingle, thereby to fasten the first PV roofing shingle or the second PV roofing shingle to the roof deck.

22. The system of claim 19, wherein each of the superstrate and the substrate is composed of at least one from the group consisting of a thermoplastic polyolefin, ethylene tetrafluoroethylene, polyolefin encapsulant, ethylene vinyl acetate encapsulant, and acrylics.

23. The system of claim 19, wherein each of the plurality of PV roofing shingles further comprises a bonding material, wherein the bonding material is between the substantially flat top surface of the roofing layer and a bottom surface of the substrate of the PV module.

24. The system of claim 19, wherein the roofing layer of each of the plurality of PV roofing shingles comprises a roofing shingle.

25. The system of claim 19, wherein in each of the plurality of PV roofing shingles the PV module is laminated with the roofing layer.

26. The system of claim 19, wherein the roofing layer of each of the plurality of PV roofing shingles comprises thermoplastic polyolefin (TPO).

27. The system of claim 19, wherein each of the plurality of PV roofing shingles further comprises an adhesive on a bottom surface of the roofing layer.

28. The system of claim 19, wherein the roofing layer has a substantially constant thickness.

29. A system, comprising:
a plurality of photovoltaic (PV) roofing shingles installed on a roof deck,
wherein the plurality of PV roofing shingles includes at least a first PV roofing shingle and a second PV roofing shingle,
wherein each of the plurality of PV roofing shingles incudes
a PV module, wherein the PV module includes
a superstrate,
a first layer, and
a substrate,
wherein a lower surface of the superstrate is juxtaposed with an upper surface of the first layer,
wherein a lower surface of the first layer is juxtaposed with an upper surface of the substrate, and
a roofing layer,
wherein the roofing layer includes
a substantially flat top surface, and
a substantially flat bottom surface opposite the substantially flat top surface,
wherein the substantially flat top surface of the roofing layer is juxtaposed with the substrate of the PV module,
wherein the substantially flat bottom surface of the first PV roofing shingle overlaps the substantially flat top surface of the second PV roofing shingle, and
wherein the roofing layer of the first PV roofing shingle partially overlaps and contacts the roofing layer of the second PV roofing shingle.

30. The system of claim 29, wherein the substantially flat top surface defines a fastener application area, wherein the roofing layer includes a first end, a second end opposite to the first end, a first edge extending between the first end and the second end, a second edge opposite to the first edge and extending between the first end and the second end, and wherein the fastener application area is spaced apart from the first edge and from the second edge, and wherein the fastener application area extends from the first end of the roofing layer to the second end of the roofing layer.

31. The system of claim 30, further comprising at least one fastener, wherein the at least one fastener penetrates the fastener application area of at least one of the first PV roofing shingle or the second PV roofing shingle, thereby to fasten the first PV roofing shingle or the second PV roofing shingle to the roof deck.

32. The system of claim 29, wherein each of the superstrate and the substrate comprises at least one material from the group consisting of a thermoplastic polyolefin, ethylene tetrafluoroethylene, polyolefin encapsulant, ethylene vinyl acetate encapsulant, and acrylics.

33. The system of claim 29, wherein each of the plurality of PV roofing shingles further includes a bonding material, wherein the bonding material is between the substantially flat top surface of the roofing layer and a bottom surface of the substrate of the PV module.

34. The system of claim 29, wherein the roofing layer of each of the plurality of PV roofing shingles comprises a roofing shingle.

35. The system of claim 29, wherein in each of the plurality of PV roofing shingles the PV module is laminated to the roofing layer.

36. The system of claim 29, wherein the roofing layer of each of the plurality of PV roofing shingles comprises thermoplastic polyolefin (TPO).

37. The system of claim 29, wherein each of the plurality of PV roofing shingles further includes an adhesive on a bottom surface of the roofing layer.

38. The system of claim 29, wherein the roofing layer has a substantially constant thickness.
